(19) United States
(12) Patent Application Publication
(10) Pub. No.: US 2024/0079287 A1
(43) Pub. Date: Mar. 7, 2024

(54) METHOD FOR MANUFACTURING HIGH-HEAT-DISSIPATION MIXED SUBSTRATE, AND SEMICONDUCTOR STRUCTURE

(71) Applicant: Zhuhai ACCESS Semiconductor Co., LTD., Zhuhai City (CN)

(72) Inventors: Xianming CHEN, Zhuhai City (CN); Xiaowei XU, Zhuhai City (CN); Juchen HUANG, Zhuhai City (CN); Gao HUANG, Zhuhai City (CN); Benxia HUANG, Zhuhai City (CN); Chaobiao QIN, Zhuhai City (CN)

(73) Assignee: Zhuhai ACCESS Semiconductor Co., LTD., Zhuhai City, GD (CN)

(21) Appl. No.: 18/453,185

(22) Filed: Aug. 21, 2023

(30) Foreign Application Priority Data
Sep. 6, 2022 (CN) 2022110819146

(51) Int. Cl. H01L 23/367; H01L 21/48

(52) U.S. Cl. CPC H01L 23/367; H01L 21/4857; H01L 21/4871

(57) ABSTRACT

A method for manufacturing a high-heat-dissipation mixed substrate includes: preparing a mother substrate, the mother substrate including an insulating layer and a temporary carrier plate which are laminated; arranging a plurality of first grooves and a plurality of first cavities on the mother substrate; filling the first groove with a thermally-conductive material to form a first thermally-conductive block, and adhering an embedded device in the first cavity and filling the first cavity with the thermally-conductive material to form a second thermally-conductive block; removing the temporary carrier plate to obtain a semi-finished substrate; manufacturing circuit layers on two opposite side surfaces of the semi-finished substrate to obtain a target mother substrate; and cutting the target mother substrate along region dividing lines to obtain a mixed substrate with a side surface being a thermally-conductive surface.

### CROSS-REFERENCE TO RELATED APPLICATION

This application is based on and claims the benefit of priority from Chinese Patent Application No. 2022110819146, filed on 6 Sep. 2022, the entirety of which is incorporated by reference herein.

### TECHNICAL FIELD

The disclosure relates to the technical field of integrated circuit manufacturing, and is particularly a method for manufacturing a high-heat-dissipation mixed substrate, and a semiconductor structure.

### BACKGROUND

Mixed substrates refer to substrates including circuits and an embedded packaging device. Embedded packaging technology refers to embedding passive devices such as resistors, capacitors and inductors, and even active devices such as integrated circuit (IC) chips into a packaging substrate. In order to meet heat dissipation requirement of the embedded packaging technology, in the existing technology, a thermally-conductive copper pillar and a heat dissipation copper block are designed on a back surface of the embedded packaging device in many substrates to improve heat dissipation capacity of the substrates. However, with the continuous development of electronic technology, the product has gradually becoming miniaturized, and the integration level of the substrate is getting higher and higher. The embedded packaging device will generate more heat on the substrate, requiring higher heat dissipation requirement on the substrate. However, the commonly used embedded packaging substrates cannot meet the new heat dissipation requirement. Therefore, a new method for manufacturing a mixed substrate is urgently needed.

### SUMMARY

The disclosure aims to solve at least one of the technical problems in the existing technology to some extent.

Therefore, one object of an embodiment of the disclosure is to provide a method for manufacturing a high-heat-dissipation mixed substrate, and a semiconductor structure. A mixed substrate with a better heat dissipation performance than that of a traditional substrate can be obtained by this method.

The method for manufacturing a high-heat-dissipation mixed substrate according to an embodiment of the disclosure includes: preparing a mother substrate, where the mother substrate includes an insulating layer and a temporary carrier plate, the insulating layer and the temporary carrier plate are laminated with each other; arranging a plurality of first grooves and a plurality of first cavities on the mother substrate, where the mother substrate includes a plurality of sub-substrates and region dividing lines, and the sub-substrate includes at least one of the first cavities, the first groove is arranged to extend across two adjacent sub-substrates, the region dividing lines are configured to divide a projection pattern of the first groove in a direction perpendicular to the mother substrate into two parts, and the first groove and the first cavity both extend through the insulating layer in the direction perpendicular to the mother substrate; filling the first groove with a thermally-conductive material to form a first thermally-conductive block, and adhering an embedded device in the first cavity and filling the first cavity with the thermally-conductive material to form a second thermally-conductive block; removing the temporary carrier plate to obtain a semi-finished substrate; manufacturing circuit layers on two opposite side surfaces of the semi-finished substrate to obtain a target mother substrate; and cutting the target mother substrate along the region dividing lines to obtain a mixed substrate with a side surface being a thermally-conductive surface.

In addition, the method for manufacturing a high-heat-dissipation mixed substrate according to the above embodiment in the disclosure may also have the following additional technical features.

In an embodiment of the disclosure, the filling the first groove with a thermally-conductive material to form a first thermally-conductive block includes: filling the first groove with the thermally-conductive material by screen printing to form the first thermally-conductive block, or laminating a dry-film high thermally-conductive material and then filling the laminated material into the first groove to form the first thermally-conductive block.

In an embodiment of the disclosure, the manufacturing circuit layers on two opposite side surfaces of the semi-finished substrate to obtain a target mother substrate includes: manufacturing a first via for connection between a first circuit layer and a second circuit layer on the two side surfaces of the semi-finished substrate; manufacturing the first circuit layer on one side surface of the semi-finished substrate, and manufacturing a third circuit layer connected with the first circuit layer; and manufacturing the second circuit layer on the other side surface opposite to the one side surface of the semi-finished substrate, and manufacturing a fourth circuit layer connected with the second circuit layer.

In an embodiment of the disclosure, the manufacturing the first circuit layer on one side surface of the semi-finished substrate includes: manufacturing a first metal seed layer; laminating a photoresist material on the first metal seed layer; and exposing, developing the photoresist material, and performing an etching process to obtain the first circuit layer.

In an embodiment of the disclosure, the thermally-conductive material includes one or more thermally-conductive materials selected from a group consisting of aluminum oxide, beryllium oxide, aluminum nitride, or silicon nitride.

In an embodiment of the disclosure, the embedded device includes one of a chip, an active device or a passive device.

In another aspect, an embodiment of the disclosure further provides a high-heat-dissipation mixed substrate, where the mixed substrate is obtained by the method for manufacturing a mixed substrate according to any one of the embodiments above, and includes the first thermally-conductive block, the second thermally-conductive block, the embedded device and the circuit layers; the first thermally-conductive block is arranged on the side surface of the mixed substrate; and the second thermally-conductive block is arranged between the embedded device and the circuit layers.

In an embodiment of the disclosure, one or more embedded devices are provided.

In an embodiment of the disclosure, one or more first thermally-conductive blocks are provided.

In another aspect, an embodiment of the disclosure further provides a semiconductor structure, including at least one high-heat-dissipation mixed substrate according to any one of the embodiments above.

The advantages and beneficial effects of the disclosure will be given in part in the following description, and will become apparent in part from the following description, or will be learned through the practice of the disclosure.

According to the disclosure, the first groove and the first cavity capable of adhering the embedded device may be arranged on the mother substrate including a plurality of sub-substrates and region dividing lines, the first groove and the first cavity are filled with the thermally-conductive material, the circuits are manufactured on the mother substrate filled with the thermally-conductive material, and finally, the mother substrate is cut along the region dividing lines to obtain the mixed substrate with the side surface being the thermally-conductive surface, and the thermally-conductive surface of the mixed substrate can dissipate heat for the circuit layers on the substrate. Moreover, the second thermally-conductive block filled in the second cavity can conduct heat generated by the embedded device to the circuit layers on the substrate, and then heat of the circuit layers is quickly conducted to the external environment through the thermally-conductive surface of the mixed substrate, so that overall heat dissipation efficiency of the mixed substrate can be improved.

### BRIEF DESCRIPTION OF THE DRAWINGS

FIG. 1 is a flow chart of a method for manufacturing a high-heat-dissipation mixed substrate according to an embodiment of the disclosure;

FIG. 2 is a flow chart of manufacturing circuit layers on two opposite side surfaces of the semi-finished substrate to obtain a target mother substrate according to an embodiment of the disclosure;

FIG. 3 is a flow chart of manufacturing the first circuit layer on one side surface of the semi-finished substrate according to an embodiment of the disclosure;

FIG. 4 is a schematic structural diagram of the mother substrate according to an embodiment of the disclosure;

FIG. 5 is a schematic structural diagram of the mother substrate with a first groove and a first cavity according to an embodiment of the disclosure;

FIG. 6 is a top view of the mother substrate with the first groove and the first cavity according to an embodiment of the disclosure;

FIG. 7 is a schematic structural diagram of the mother substrate filled with a thermally-conductive material and adhered with an embedded device according to an embodiment of the disclosure;

FIG. 8 is a top view of the mother substrate filled with the thermally-conductive material and adhered with the embedded device according to an embodiment of the disclosure;

FIG. 9 is a schematic structural diagram of a semi-finished substrate according to an embodiment of the disclosure;

FIG. 10 is a schematic diagram showing a structural change of a target mother substrate obtained on the semi-finished substrate according to an embodiment of the disclosure; and

FIG. 11 is a schematic structural diagram of a mixed substrate according to an embodiment of the disclosure.

### DETAILED DESCRIPTION

Embodiments of the disclosure are described in detail hereinafter with reference to the drawings to explain the principles and processes of a method for manufacturing a mixed substrate, a mixed substrate and a semiconductor structure in the embodiments of the disclosure as follows.

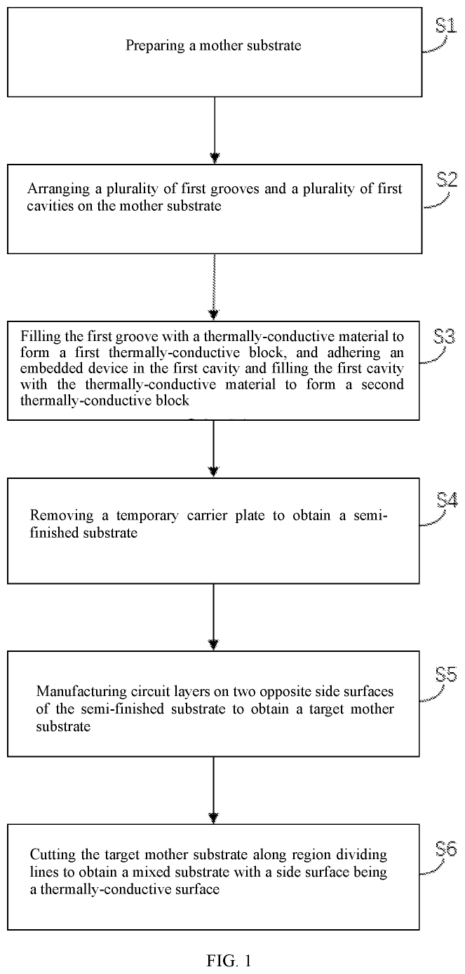

With reference to FIG. 1, a method for manufacturing a high-heat-dissipation mixed substrate according to the disclosure includes the following steps.

In S1, a mother substrate is prepared.

Optionally, the mother substrate of the disclosure may include an insulating layer and a temporary carrier plate, where the insulating layer and the temporary carrier plate may be laminated, bonded and physically combined in other forms, and the temporary carrier plate needs to be physically removed in the subsequent process, so that the temporary carrier plate may be made of a heat-peelable material, or a sticky material such as a high-temperature adhesive tape. The insulating layer may be made of a glass fiber material or other insulating materials. Specifically, the temporary carrier plate is made of the high-temperature adhesive tape, and the high-temperature adhesive tape has thermal stability and is not easy to change in physical and chemical properties at high temperature. Moreover, because the mixed substrate needs an embedded device, the high-temperature adhesive tape with viscidity may also fix the embedded device.

In S2, a plurality of first grooves and a plurality of first cavities are arranged on the mother substrate.

In some embodiments of the disclosure, the first groove and the first cavity may be arranged by physical means such as milling or gonging, or by chemical means such as chemical etching. The mother substrate may include a plurality of sub-substrates and region dividing lines. Projection areas of the plurality of sub-substrates in a direction perpendicular to the mother substrate may be the same, or partially the same, or the projection area may be different between every two sub-substrates. The first groove may be configured for filling a thermally-conductive material, and the first groove may be arranged across any two sub-substrates. The region dividing lines may divide the first groove into two parts along the direction perpendicular to the mother substrate. Projection areas of the divided two parts in the direction perpendicular to the mother substrate may be the same or different. The first cavity may be configured for adhering the embedded device, the first cavity may be arranged in any position of each sub-substrate, and may be arranged in a center of the sub-substrate, or arranged close to the first groove, or connected with the first groove, and the first cavity and the first groove may both extend through the insulating layer of the mother substrate along the direction perpendicular to the substrate.

In S3, the first groove is filled with the thermally-conductive material to form a first thermally-conductive block, and the embedded device is adhered in the first cavity and the first cavity is filled with the thermally-conductive material to form a second thermally-conductive block.

In some embodiments of the disclosure, the first groove may be filled with the thermally-conductive material to form the first thermally-conductive block, and the first cavity needs to be adhered with the embedded device first and then filled with the thermally-conductive material, so that the thermally-conductive material forms the second thermally-conductive block. The first thermally-conductive block may be configured for heat dissipation of the circuit layer of the mixed substrate, and the second thermally-conductive block may be configured for heat dissipation of the embedded device in the first cavity. Because neither the first thermally-conductive block nor the second thermally-conductive block participates in interlayer electrical conduction of the mixed substrate, the thermally-conductive block may be made of an insulating material with a high thermally-conductive performance.

In S4, the temporary carrier plate is removed to obtain a semi-finished substrate.

In some embodiments of the disclosure, the temporary carrier plate may fix the thermally-conductive material during manufacturing of the mixed substrate, so that the thermally-conductive material does not overflow in a direction opposite to a filling direction during filling of the thermally-conductive material. Because the temporary carrier plate and the insulating layer are connected by bonding or laminating, the temporary carrier plate may be removed physically. It should be noted that the temporary carrier plate may also be removed chemically, such as being removed with a chemical agent capable of etching the temporary carrier plate, and in this case, the chemical agent cannot etch the thermally-conductive block and the insulating layer.

In S5, circuit layers are manufactured on two opposite side surfaces of the semi-finished substrate to obtain a target mother substrate.

In some embodiments of the disclosure, after obtaining the semi-finished substrate, it is necessary to manufacture the circuit layers on the semi-finished substrate. Before manufacturing the circuit layers, a surface of the semi-finished substrate at one side of the semi-finished substrate filled with the thermally-conductive material needs to be flattened due to a possible uneven or overflowing condition during filling of the thermally-conductive material, which may be realized by a machine grinding or etching method. After flattening, the circuit layers may be manufactured on two opposite side surfaces of the semi-finished substrate to finally obtain the target mother substrate. It should be noted that the target mother substrate may include the circuit layer and the circuit layers on the semi-finished substrate, the circuit layer may be a single-layer circuit layer or a multi-layer circuit layer, and a specific number of the circuit layer may be selected according to a specific function.

In S6, the target mother substrate is cut along the region dividing lines to obtain a mixed substrate with a side surface being a thermally-conductive surface.

In some embodiments of the disclosure, after obtaining the target mother substrate with the circuit layers, the target mother substrate may be cut along the region dividing lines to divide the target mother substrate into a plurality of mixed substrates. Because the region dividing lines may divide a projection pattern in a direction of the mother substrate into two parts, the side surface of the mixed substrate cut along the region dividing lines is the thermally-conductive surface, and the thermally-conductive surface can quickly conduct heat generated by the circuit layers to the external environment, thus achieving a heat dissipation effect, and the second thermally-conductive block in the first cavity on the mixed substrate can conduct heat generated by the embedded device to the circuit layers, thus conducting the heat to the external environment through the thermally-conductive surface.

Further, the filling the first groove with a thermally-conductive material to form a first thermally-conductive block may include: filling the first groove with the thermally-conductive material by screen printing to form the first thermally-conductive block, or laminating a dry-film high thermally-conductive material and then filling the laminated material into the first groove to form the first thermally-conductive block.

In some embodiments of the disclosure, when the thermally-conductive material is filled, the thermally-conductive material may be filled into the first groove by screen printing. In this case, the thermally-conductive material may be insulating and thermally-conductive filler ink, which forms the first thermally-conductive block after thermal curing, or a new dry-film high thermally-conductive material, which is laminated and then filled into the first groove to form the first thermally-conductive block. The first thermally-conductive block may conduct the heat of the circuit layer, so as to avoid a high temperature from affecting the realization of circuit function.

In addition, it should be noted that, for the second thermally-conductive block, the thermally-conductive material may also be filled into the first cavity adhered with the embedded device by screen printing. In this case, the thermally-conductive material may be insulating and thermally-conductive filler ink, which forms the second thermally-conductive block after thermal curing, or a new dry-film high thermally-conductive material, which is laminated and then filled into the first cavity to form the second thermally-conductive block. The second thermally-conductive block may conduct the heat of the device, so as to avoid a high temperature from affecting a service life of the device.

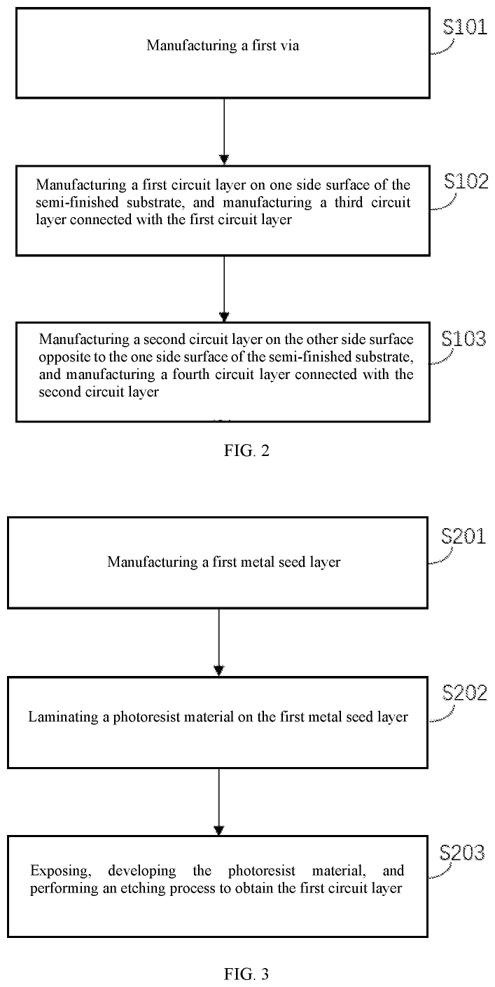

Further, with reference to FIG. 2, the manufacturing circuit layers on two opposite side surfaces of the semi-finished substrate to obtain a target mother substrate may include the following steps S101-S103.

In S101, a first via is manufactured.

In some embodiments of the disclosure, the first via may be a via for mutually conducting the circuit layers on two side surfaces of the semi-finished substrate. One or more first vias may be provided, and the first via may be arranged in any position of the insulating layer. The first via may extend through the insulating layer of the semi-finished substrate along the direction perpendicular to the semi-finished substrate. When the first via is manufactured, the semi-finished substrate may be drilled first to form a through hole, and then the through hole is metallized, which may be implemented using an electroplating process.

In S102, the first circuit layer is manufactured on one side surface of the semi-finished substrate, and a third circuit layer connected with the first circuit layer is manufactured.

In some embodiments of the disclosure, the first circuit layer is a circuit layer on one side surface of the semi-finished substrate, and the third circuit layer may be a circuit layer connected with the first circuit layer, and the third circuit layer may be a single-layer or multi-layer circuit layer. After manufacturing the first circuit layer, the third circuit layer connected with the first circuit layer may be continuously manufactured on the basis of the first circuit layer.

In S103, the second circuit layer is manufactured on the other side surface opposite to the one side surface of the semi-finished substrate, and a fourth circuit layer connected with the second circuit layer is manufactured.

In some embodiments of the disclosure, the second circuit layer is a circuit layer on the other side surface opposite to the one side surface of the semi-finished substrate, and the fourth circuit layer may be a circuit layer connected with the second circuit layer, and the fourth circuit layer may be a single-layer or multi-layer circuit layer. After manufacturing the second circuit layer, the fourth circuit layer connected with the second circuit layer may be continuously manufactured on the basis of the second circuit layer to finally form the target mother substrate with interconnected multi-layer circuits on two sides of the substrate.

Further, with reference to FIG. 3, the manufacturing the first circuit layer on one side surface of the semi-finished substrate may include the following steps S201-S203.

In S201, a first metal seed layer is manufactured.

In some embodiments of the disclosure, the first metal seed layer may be used as a basis for manufacturing the first circuit layer, the first metal seed layer may be obtained by the electroplating process, and the first metal seed layer may completely cover one side surface of the semi-finished substrate.

In S202, a photoresist material is laminated on the first metal seed layer.

In some embodiments of the disclosure, after obtaining the first metal seed layer, the photoresist material may be laminated on the seed layer, and the photoresist material may protect the circuit layer that does not need to be etched.

In S203, the photoresist material is exposed, developed, and etching process is performed to obtain the first circuit layer.

In some embodiments of the disclosure, a developed circuit image of a part to be etched may be obtained after the photoresist material is exposed and developed, and the circuit layer corresponding to the exposed and developed photoresist material may be removed through the etching process, thus obtaining the first circuit layer.

It should be noted that the step of manufacturing the second circuit layer may be the same as the step of manufacturing the first circuit layer, which is also to obtain the second circuit layer by manufacturing the seed layer, and exposing, developing and etching. Alternatively, the second circuit layer may be obtained by other existing processes.

Further, in some embodiments of the disclosure, the thermally-conductive material may include one or more thermally-conductive materials selected from a group consisting of aluminum oxide, beryllium oxide, aluminum nitride, or silicon nitride, where the aluminum oxide, the beryllium oxide, the aluminum nitride and the silicon nitride are all materials with a good thermally-conductive performance, and may conduct heat efficiently, thus realizing efficient heat dissipation of the substrate. Moreover, the thermally-conductive materials can increase the rigidity of the substrate and effectively improve the warpage of the product.

Further, in some embodiments of the disclosure, the embedded device of the mixed substrate may include one of a chip, an active device or a passive device. One or more embedded devices may be provided, and a specific number of the embedded devices may be set according to actual application.

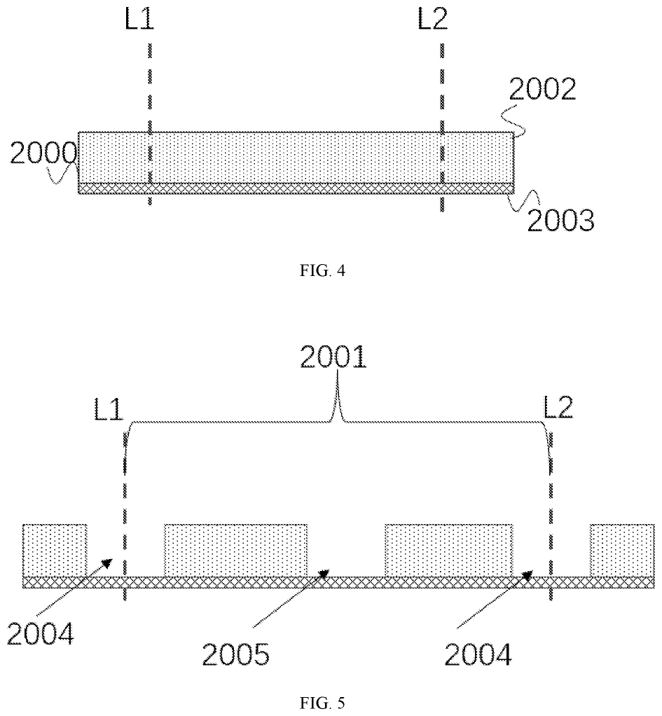

Specifically, with reference to FIG. 4 to FIG. 11, the method and principle for manufacturing the mixed substrate of the disclosure are described as follows.

Firstly, a mother substrate 2000 needs to be prepared. With reference to FIG. 4, the mother substrate 2000 has a two-layer structure including an insulating layer 2002 and a temporary carrier plate 2003, and the insulating layer 2002 and the temporary carrier plate 2003 are bonded to form the mother substrate 2000.

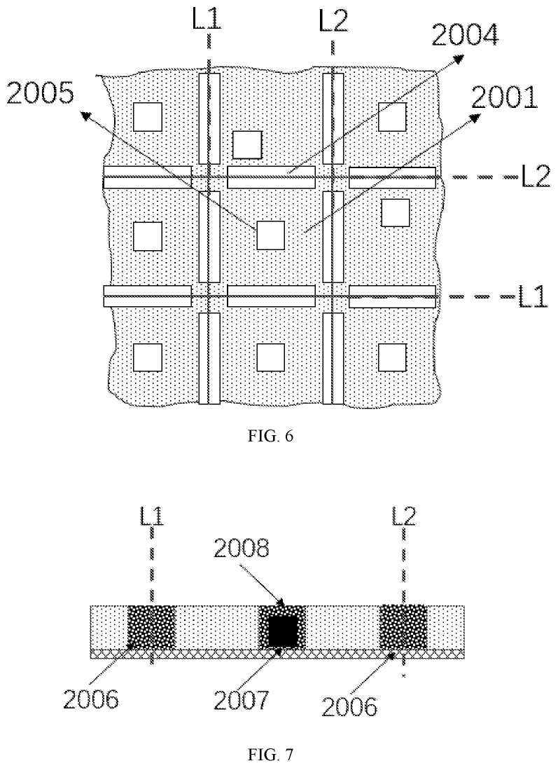

Then, a plurality of first grooves 2004 and a plurality of first cavities 2005 are arranged on the mother substrate 2000, and the first grooves 2004 and the first cavities 2005 are arranged in a way as shown in FIG. 5 and FIG. 6. In FIG. 5 and FIG. 6, the mother substrate 2000 includes a plurality of sub-substrates 2001 and region dividing lines L1 and L2, and the sub-substrate 2001 includes at least one first cavity 2005. The first groove 2004 is arranged across two adjacent sub-substrates 2001. The region dividing lines L1 and L2 may be used to divide the projection pattern of the first groove 2004 in the direction perpendicular to the mother substrate 2000 into two parts. The first groove 2004 and the first cavity 2005 both extend through the insulating layer 2002 in the direction perpendicular to the mother substrate 2000.

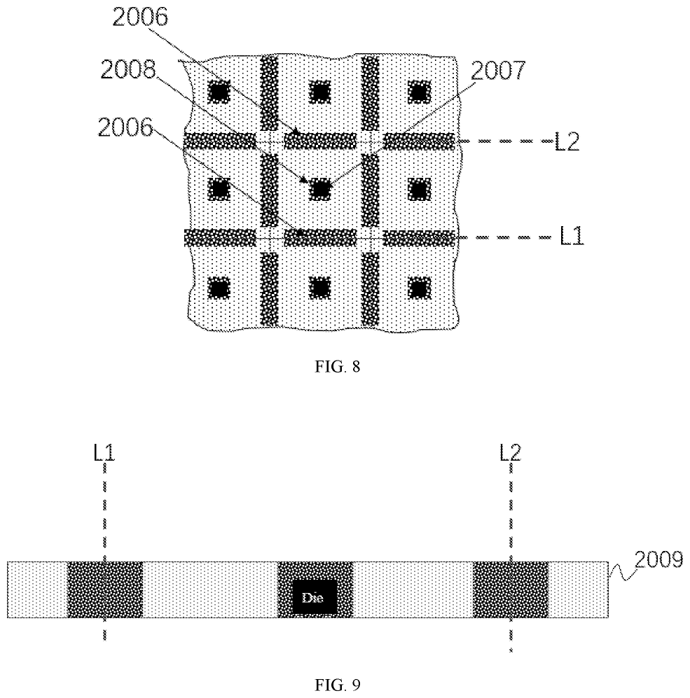

Then, with reference to FIG. 7 and FIG. 8, the first groove 2004 is filled with a thermally-conductive material to form a first thermally-conductive block 2006, and the embedded device 2007 is adhered in the first cavity 2005 and the first cavity is filled with the thermally-conductive material to form a second thermally-conductive block 2008.

Then, with reference to FIG. 9, the temporary carrier plate 2003 is removed to obtain a semi-finished substrate 2009.

Then, with reference to FIG. 10, a first circuit layer 2010 and a second circuit layer 2011 which are interconnected are manufactured on two opposite side surfaces of the semi-finished substrate 2009, and then a third circuit layer 2012 is manufactured on the first circuit layer 2010 and a fourth circuit layer 2013 is manufactured on the second circuit layer 2011 to finally obtain a target mother substrate 2014 with multi-layer circuits.

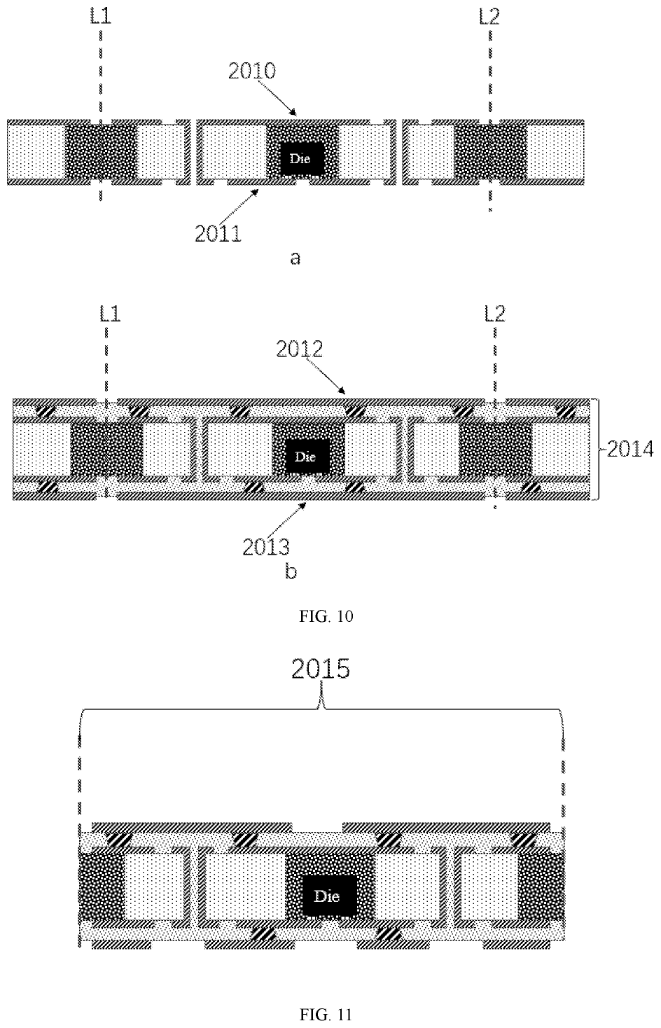

Finally, with reference to FIG. 11, the target mother substrate 2014 is cut along the region dividing lines L1 and L2, and the first thermally-conductive block 2006 is divided into two parts to finally obtain the mixed substrate 2015 with the side surface being the thermally-conductive surface.

In addition, the embodiment of the disclosure further provides a high-heat-dissipation mixed substrate, and the mixed substrate may be manufactured by the method for manufacturing a mixed substrate described in any one of the above embodiments, and includes the first thermally-conductive block, the second thermally-conductive block, the embedded device and the circuit layers. The first thermally-conductive block may be arranged on the side surface of the mixed substrate. The second thermally-conductive block may be arranged between the embedded device and the circuit layer, and the first thermally-conductive block may conduct heat generated by the circuit layer of the mixed substrate to the external environment in time, thus achieving a quick heat dissipation effect, and the second thermally-conductive block is arranged between the embedded device and the circuit layer, so that heat generated by the embedded device may be conducted to the circuit layer in time, and the heat dissipation of the embedded device may be completed through the first thermally-conductive block, thus finally making the mixed substrate have an efficient heat dissipation performance.

Further, in some embodiments of the disclosure, one or more embedded devices in the mixed substrate may be provided, and there are typically a plurality of embedded devices in one mixed substrate. In order to maintain overall heat dissipation function, a corresponding thermally-conductive block needs to be arranged between each embedded device and the circuit layer, so that all embedded devices on the whole substrate may dissipate heat in time, thus making the embedded device on the substrate have a longer service life, and a specific number of the embedded devices may be determined according to circuit function and effect realized by the actual substrate.

Further, in some embodiments of the disclosure, one or more first thermally-conductive blocks may be provided. Because the first thermally-conductive block may be configured for heat dissipation of the circuit layer on the substrate, the first thermally-conductive block may be arranged on the side surface of the substrate. The substrate has four side surfaces, each side surface may be provided with one thermally-conductive block, the thermally-conductive block may conduct heat with the external environment through the side surface, and the first thermally-conductive block may be connected with the circuit layer on the substrate in the direction perpendicular to the substrate. The first thermally-conductive block can not only realize the heat dissipation of the circuit layer, but also conduct the heat conducted to the circuit layer by the embedded device to the external environment, thus realizing the heat dissipation of the embedded device.

The embodiment of the disclosure further provides a semiconductor structure, where the semiconductor structure may include at least one mixed substrate according to any one of the embodiments above. Because of having at least one mixed substrate with an efficient heat dissipation performance, the semiconductor structure can also realize the efficient heat dissipation of the device and the circuit, so as to avoid the device or the circuit from being overheated to reduce a service life of the semiconductor structure when the semiconductor structure realizes the circuit function, and save a cost while improving the stability of the semiconductor device.

In some optional embodiments, the functions/operations mentioned in the block diagram may occur without following the sequence mentioned in the operation diagram. For example, depending on the functions/operations involved, two blocks shown consecutively may actually be executed substantially simultaneously or the blocks may sometimes be executed in the reverse sequence. In addition, the embodiments presented and described in the flow chart of the disclosure are provided by way of example, with the purpose of providing more comprehensive understanding of the technology. The disclosed method is not limited to the operation and logic flow presented herein. The optional embodiments are expectable, where a sequence of various operations may be changed and a sub-operation described as a part of a large-scale operation may be independently executed.

In addition, although the disclosure is described in the context of functional modules, it should be understood that, unless otherwise stated, one or more of the functions and/or features may be integrated in a single physical apparatus and/or software module, or one or more functions and/or features may be implemented in separate physical apparatus or software modules. It can also be understood that, a detailed discussion about the actual implementation of each module is not necessary for understanding the disclosure. More specifically, considering the attributes, functions and internal relations of various functional modules in the apparatus disclosed herein, the actual implementation of the module will be known within conventional technologies of an engineer. Therefore, those of ordinary skills in the art can implement the disclosure explained in the claims without undue experimentation by applying common technologies. It can also be understood that, the specific concepts disclosed are only illustrative and not intended to limit the scope of the disclosure, and the scope of the disclosure is determined by the appended claims and the full scope of equivalent solutions of the claims.

In the descriptions above in the specification, the descriptions of the reference terms “an implementation/embodiment”, “another implementation/embodiment” or “some implementations/embodiments” refer to that the specific features, structures, materials, or characteristics described in combination with the implementation or example are included in at least one implementation or example of the disclosure. In the specification, the schematic expressions of the above terms do not necessarily refer to the same implementation or example. Furthermore, the specific features, structures, materials, or characteristics described may be combined in any one or more implementations or examples in a suitable manner.

Although the implementations of the disclosure have been shown and described, those of ordinary skills in the art should understand that: various changes, amendments, substitutions and modifications can be made to these implementations without departing from the principles and purposes of the disclosure, and the scope of the disclosure is limited by the claims and equivalents thereof.

The foregoing describes the preferred embodiments of the disclosure in detail, but the disclosure is not limited to the above embodiments. Those of ordinary skills in the art may further make various equivalent modifications or substitutions without violating the gist of the disclosure, and these equivalent modifications or substitutions are included in the scope defined by the claims of the disclosure.

What is claimed is:

1. A method for manufacturing a high-heat-dissipation mixed substrate, comprising:
preparing a mother substrate, wherein the mother substrate comprises an insulating layer and a temporary carrier plate, the insulating layer and the temporary carrier plate are laminated with each other;
arranging a plurality of first grooves and a plurality of first cavities on the mother substrate, wherein the mother substrate comprises a plurality of sub-substrates and region dividing lines, and the sub-substrate comprises at least one of the first cavities, the first groove is arranged to extend across two adjacent sub-substrates, the region dividing lines are configured to divide a projection pattern of the first groove in a direction perpendicular to the mother substrate into two parts, and the first groove and the first cavity both extend through the insulating layer in the direction perpendicular to the mother substrate;
filling the first groove with a thermally-conductive material to form a first thermally-conductive block, and adhering an embedded device in the first cavity and filling the first cavity with the thermally-conductive material to form a second thermally-conductive block;
removing the temporary carrier plate to obtain a semi-finished substrate;
manufacturing circuit layers on two opposite side surfaces of the semi-finished substrate to obtain a target mother substrate; and
cutting the target mother substrate along the region dividing lines to obtain a mixed substrate with a side surface being a thermally-conductive surface.

2. The method for manufacturing a high-heat-dissipation mixed substrate according to claim 1, wherein the filling the first groove with a thermally-conductive material to form a first thermally-conductive block comprises:
filling the first groove with the thermally-conductive material by screen printing to form the first thermally-conductive block, or laminating a dry-film high thermally-conductive material and then filling the laminated material into the first groove to form the first thermally-conductive block.

3. The method for manufacturing a high-heat-dissipation mixed substrate according to claim 1, wherein the manufacturing circuit layers on two opposite side surfaces of the semi-finished substrate to obtain a target mother substrate comprises:
manufacturing a first via for connection between a first circuit layer and a second circuit layer on the two side surfaces of the semi-finished substrate;
manufacturing the first circuit layer on one side surface of the semi-finished substrate, and manufacturing a third circuit layer connected with the first circuit layer; and
manufacturing the second circuit layer on the other side surface opposite to the one side surface of the semi-finished substrate, and manufacturing a fourth circuit layer connected with the second circuit layer.

4. The method for manufacturing a high-heat-dissipation mixed substrate according to claim 3, wherein the manufacturing the first circuit layer on one side surface of the semi-finished substrate comprises:
manufacturing a first metal seed layer;
laminating a photoresist material on the first metal seed layer; and
exposing, developing the photoresist material, and performing an etching process to obtain the first circuit layer.

5. The method for manufacturing a high-heat-dissipation mixed substrate according to claim 2, wherein the thermally-conductive material comprises one or more thermally-conductive materials selected from a group consisting of aluminum oxide, beryllium oxide, aluminum nitride, or silicon nitride.

6. The method for manufacturing a high-heat-dissipation mixed substrate according to claim 1, wherein the embedded device comprises one of a chip, an active device or a passive device.

7. A high-heat-dissipation mixed substrate, wherein the mixed substrate is obtained by the method for manufacturing a mixed substrate according to claim 1, and comprises the first thermally-conductive block, the second thermally-conductive block, the embedded device and the circuit layers; the first thermally-conductive block is arranged on the side surface of the mixed substrate, so that the side surface of the mixed substrate is the thermally-conductive surface; and the second thermally-conductive block is arranged between the embedded device and the circuit layers.

8. The high-heat-dissipation mixed substrate according to claim 7, wherein one or more embedded devices are provided.

9. The high-heat-dissipation mixed substrate according to claim 7, wherein one or more first thermally-conductive blocks are provided.

10. A semiconductor structure, comprising at least one high-heat-dissipation mixed substrate according to claim 7.
